(19) United States
(12) Patent Application Publication
(10) Pub. No.: US 2019/0371625 A1
(43) Pub. Date: Dec. 5, 2019

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Ken SAKAMOTO, Tokyo (JP)

(73) Assignee: Mitsubishi Electric Corporation, Tokyo (JP)

(21) Appl. No.: 16/473,560

(22) PCT Filed: Feb. 27, 2017
(86) PCT No.: PCT/JP2017/007311

§ 371 Date: Jun. 25, 2019

(51) Int. Cl. H01L 21/56; H01L 23/29; H01L 23/31; H01L 23/495

(52) U.S. Cl. CPC H01L 21/565; H01L 21/561; H01L 23/291; H01L 23/49568; H01L 23/3135; H01L 23/49586; H01L 23/3121

(57) ABSTRACT

A semiconductor device includes a lead frame, a semiconductor chip fixed to an upper surface of the lead frame, a first resin in contact with a lower surface of the lead frame, and a second resin provided on the first resin, wherein the first resin is higher in heat conductivity than the second resin, and the first resin and the second resin cover the semiconductor chip.

### FIELD

The present invention relates to a semiconductor device in which a semiconductor chip is resin-sealed, and a method for manufacturing the semiconductor device.

### BACKGROUND

Patent Literature 1 discloses a technology of forming a molding resin on a workpiece. Specifically, after a resin for a pot is fed into a pot, a resin for a cavity is fed into a recess part of a cavity. Next, by performing mold clamping of a mold, the resin for the pot and the resin for the cavity both of which have been melted are pressed with a plunger so as to be mixed, and the recess part of the cavity is filled with the molten resin. Next, the molten resin in the recess part of the cavity is maintained at a predetermined resin pressure to be cured under heating.

### PRIOR ART

### Patent Literature

Patent Literature 1: JP 2012-166432 A

### SUMMARY

### Technical Problem

In a semiconductor device in which a semiconductor chip fixed to a lead frame is resin-sealed, it is necessary to downsize the device, to enhance the heat dissipation property of the device, and to enhance the insulation property in order to protect the semiconductor chip from unintentional electric influence. It is required to provide a semiconductor device low in cost and high in quality.

The present invention is devised in order to solve the aforementioned problems, and an object thereof is to provide a semiconductor device low in cost and high in quality, and a method for manufacturing the semiconductor device.

### Means for Solving the Problems

According to a present invention, a semiconductor device includes a lead frame, a semiconductor chip fixed to an upper surface of the lead frame, a first resin in contact with a lower surface of the lead frame, and a second resin provided on the first resin, wherein the first resin is higher in heat conductivity than the second resin, and the first resin and the second resin cover the semiconductor chip.

According to a present invention, a method for manufacturing a semiconductor device includes a resin providing step of providing a plunger chip in a hole formed in a recess part of a lower mold, providing a first resin on the plunger chip, and providing a second resin lower in heat conductivity than the first resin on the first resin, a mounting step of placing a lead frame on an upper surface of which a semiconductor chip is fixed on an upper surface of the recess part, a mold clamping step of placing an upper mold on the lower mold, and performing mold clamping in a state where the semiconductor chip is housed in a cavity provided by the lower mold and the upper mold, an injecting step of raising, after melting the first resin and the second resin, the plunger chip to provide the second resin into the cavity, and by providing the first resin after that, bringing the first resin into contact with a lower surface of the lead frame, and a pressure maintaining step of exerting a pressure on the first resin and the second resin from the plunger chip, and maintaining the pressure.

According to another aspect of the present invention, a method for manufacturing a semiconductor device includes a resin providing step of providing a plunger chip in a hole formed in a recess part of a lower mold, and providing a resin on the plunger chip, a mounting step of placing a lead frame on a lower surface of which a semiconductor chip is fixed on an upper surface of the recess part, a mold clamping step of placing an upper mold on the lower mold while interposing a heat dissipating sheet higher in heat conductivity than the resin between the lead frame and the upper mold, and performing mold clamping in a state where the semiconductor chip is housed in a cavity provided by the lower mold and the upper mold, an injecting step of raising, after melting the resin, the plunger chip to provide the resin into the cavity, and a pressure maintaining step of exerting a pressure on the resin from the plunger chip, and maintaining the pressure.

According to another aspect of the present invention, a method for manufacturing a semiconductor device includes a resin providing step of providing plunger chips in holes formed in a lower mold having a plurality of recess parts, and providing resins on the plunger chips, a mounting step of placing a lead frame to which a semiconductor chip is fixed on an upper surface of the lower mold, a mold clamping step of placing an upper mold on the lower mold, and performing mold clamping in a state where a plurality of cavities formed by the plurality of recess parts and a runner gate connecting the plurality of cavities are formed, an injecting step of raising, after melting the resin, the plunger chips to a predefined position to provide the resin into the plurality of cavities and the runner gate, and a pressure maintaining step of exerting a pressure on the resin from the plunger chips, and maintaining the pressure, wherein a pressure which the resin in the runner gate exerts on a movable block in the runner gate is detected when the plunger chip is raised to the predefined position, the movable block is moved in a direction of being retracted from the runner gate when the pressure is larger than a predefined pressure, and the movable block is moved in a direction of being advanced into the runner gate when the pressure is smaller than the predefined pressure.

Other features of the present invention will be made clear in the following.

### Advantageous Effects of Invention

According to this invention, for example, the first resin high in heat conductivity is provided on the lower surface of the lead frame, meanwhile, the second resin lower in heat conductivity than the first resin is provided on the lead frame, and thereby, a semiconductor device low in cost and high in quality can be provided.

### BRIEF DESCRIPTION OF THE DRAWINGS

FIG. 1 is a cross-sectional view of a semiconductor device according to Embodiment 1.

FIG. 2 is a flowchart illustrating a method for manufacturing a semiconductor device according to Embodiment 1.

FIG. 3 is a cross-sectional view of a first resin and a second resin.

FIG. 4 is a cross-sectional view of the lead frame and the like.

FIG. 5 is a cross-sectional view illustrating the lower mold and the upper mold which have undergone mold clamping.

FIG. 6 is a cross-sectional view illustrating the plunger chip being raised.

FIG. 7 is a cross-sectional view of ball plungers and the like.

FIG. 8 is a plan view of the ball plungers and the like.

FIG. 9 is a perspective view of a plurality of plunger rods and the like.

FIG. 10 is a cross-sectional view of molds and the like corresponding to the plunger apparatus in FIG. 9.

FIG. 11 is a cross-sectional view illustrating a method for manufacturing a semiconductor device according to Embodiment 2.

FIG. 12 is a flowchart representing a method for manufacturing a semiconductor device according to Embodiment 3.

FIG. 13 shows a configuration of an apparatus used for manufacturing a semiconductor device.

FIG. 14 is a view illustrating the resin provided into the cavities and the runner gate.

FIG. 15 is a diagram illustrating an exemplary configuration of the controller.

FIG. 16 is a diagram illustrating another exemplary configuration of the controller.

FIG. 17 is a view illustrating a method for manufacturing a semiconductor device according to Embodiment 4.

FIG. 18 is a view illustrating a method for manufacturing a semiconductor device according to a comparative example.

### DESCRIPTION OF EMBODIMENTS

Semiconductor devices and methods for manufacturing a semiconductor device according to embodiments of the present invention are described with reference to the drawings. The same or corresponding constituents are given the same signs and their repeated description is occasionally omitted.

### Embodiment 1

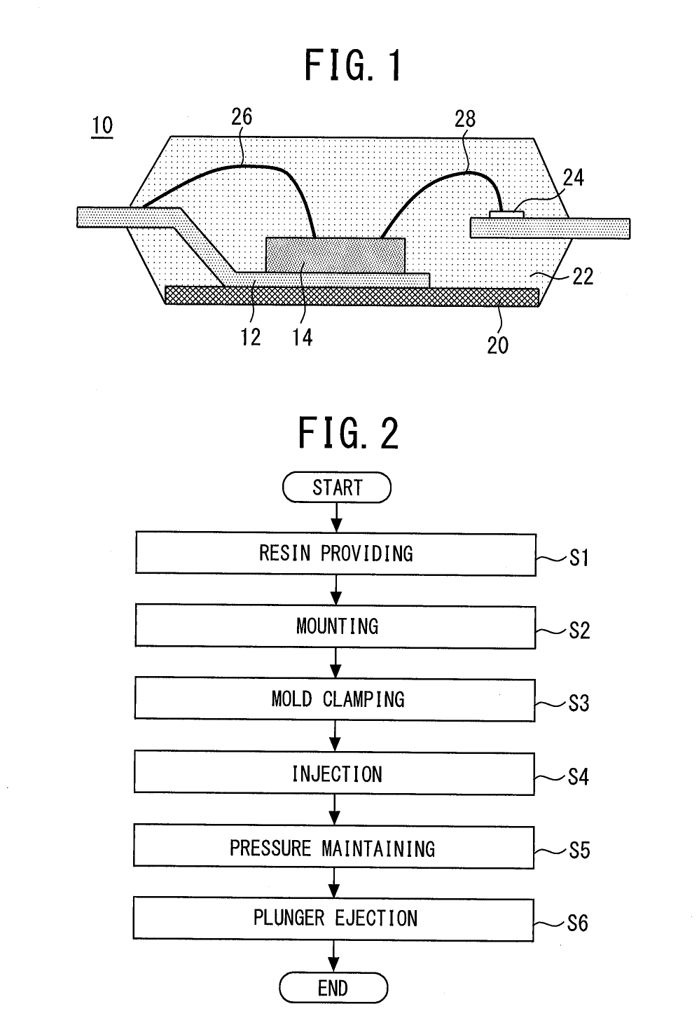

FIG. 1 is a cross-sectional view of a semiconductor device 10 according to Embodiment 1 of the present invention. The semiconductor device 10 includes a lead frame 12. A semiconductor chip 14 is fixed to the upper surface of the lead frame 12. The semiconductor chip 14 is, for example, a switching device formed of Si or SiC. A first resin 20 is in contact with the lower surface of the lead frame 12. On this first resin 20, a second resin 22 is provided. The semiconductor chip 14 is covered by the first resin 20 and the second resin 22. The first resin 20 and the second resin 22 function as a package. The first resin 20 is higher in heat conductivity than the second resin 22. The materials of the first resin 20 and the second resin 22 are not specially limited as long as this condition is satisfied. The first resin 20 is, for example, alumina, and the second resin 22 is, for example, silica. The heat conductivity of the first resin 20 is preferably 2 W/m·K or more.

The lead frame 12 has a die pad part to which the semiconductor chip 14 is fixed, an inner lead part provided in the resin, and an outer lead part extending outward of the resin. A control chip 24 which outputs a control signal to the semiconductor chip 14 is provided on the inner lead part which is in the second resin 22. The semiconductor chip 14 and the inner lead part are connected to each other with a wire 26. The semiconductor chip 14 and the control chip 24 are connected to each other with a wire 28.

The first resin 20 is provided only below the lower surface of the lead frame 12. The first resin 20 is in contact with the lower surface of the semiconductor chip 14 via the lead frame 12, and the second resin 22 is in contact with the lateral surface and the upper surface of the semiconductor chip 14. The package is mostly the second resin 22, and the volume occupying the first resin 20 out of the whole package is small. Accordingly, the second resin 22 is larger in volume than the first resin 20. The first resin 20 is exposed below the semiconductor chip 14, and the second resin 22 is exposed above the semiconductor chip 14.

FIG. 2 is a flowchart illustrating a method for manufacturing a semiconductor device according to Embodiment 1 of the present invention. With this flowchart, a method for manufacturing the semiconductor device 10 is described. First, in step S1, a first resin and a second resin are provided on a plunger chip.

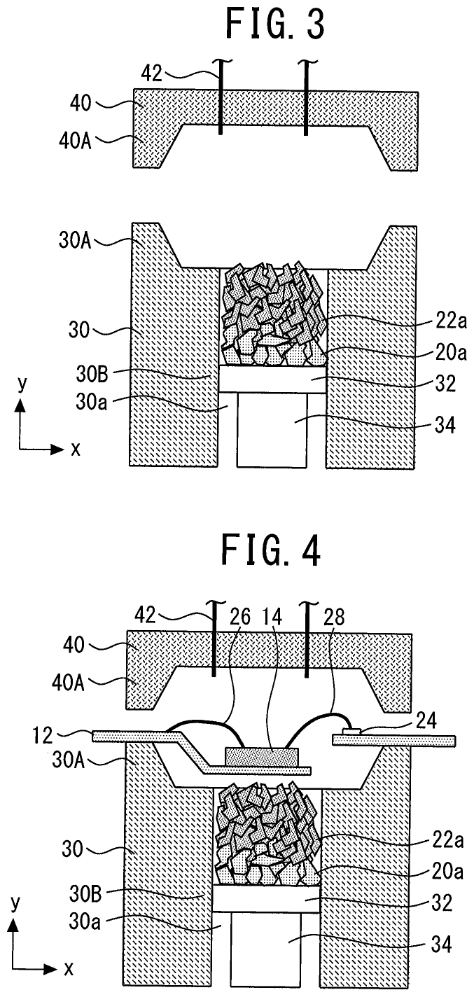

FIG. 3 is a diagram illustrating a first resin 20a and a second resin 22a. A lower mold 30 has a recess part 30A. A hole 30a is formed in this recess part 30A. A portion in which the hole 30a is formed is referred to as a pot 30B. A plunger chip 32 is provided in the hole 30a. The lateral surface of the plunger chip 32 is in contact with the pot 3013. The plunger chip 32 is supported by a plunger rod 34. When the plunger rod 34 moves in the positive and negative y-directions, the plunger chip 32 also moves interlockingly in the positive and negative y-directions.

The first resin 20a is provided on such a plunger chip 32, and the second resin 22a lower in heat conductivity than the first resin 20a is provided on the first resin 20a. The first resin 20a and the second resin 22a are granular. For example, the first resin 20a is granular alumina, and the second resin 22a is granular silica. A step of providing resin on the plunger chip 32 as above is referred to as a resin providing step.

FIG. 3 also illustrates an upper mold 40. The upper mold 40 has a recess part 40A. Movable pins 42 penetrating the recess part 40A are provided. The movable pins 42 penetrate the recess part 40A and can move in the positive and negative y-directions. Such movement can be realized by a motor.

Next, the process is put forward to step S2. In step S2, the lead frame 12 is placed on the lower mold 30. FIG. 4 illustrates the lead frame 12 placed on the lower mold 30. In step S2, the lead frame 12 to the upper surface of which the semiconductor chip 14 is fixed is placed on the upper surface of the recess part 30A of the lower mold 30. This step is referred to as a mounting step.

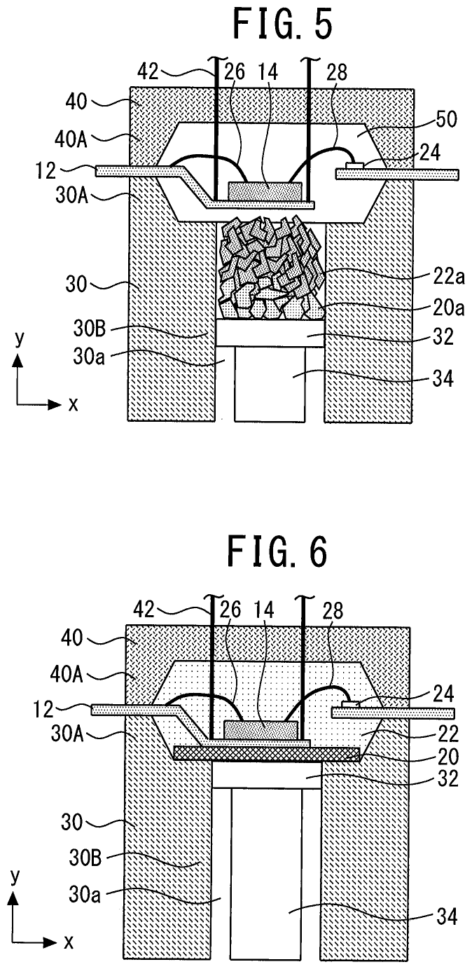

Next, the process is put forward to step S3. In step S3, mold clamping is performed with the lower mold 30 and the upper mold 40. FIG. 5 is a view illustrating the lower mold 30 and the upper mold 40 which have undergone mold clamping. The lower mold 30 and the upper mold 40 are housed in a mold clamping apparatus, the upper mold 40 is placed on the lower mold 30, and predefined mold clamping force is exerted on these. In this stage, the mold clamping is performed in the state where the semiconductor chip 14 is housed in a cavity 50 provided by the lower mold 30 and the upper mold 40. This step is referred to as a mold clamping step.

In the mold clamping step, the movable pins 42 are brought into contact with the upper surface of the lead frame 12. The movable pins 42 suppress the lead frame 12 from floating upward while injecting the resin into the cavity 50 and maintaining a pressure. In order to securely prevent such floating, a plurality of movable pins 42 are preferably brought into contact with the upper surface of the lead frame 12.

Next, the process is put forward to step S4. In step S4, after the first resin 20a and the second resin 22a are melted, the plunger chip 32 is raised. FIG. 6 is a view illustrating the plunger chip 32 being raised. While the plunger chip 32 is being raised, first, the second resin 22a is provided into 50 of the cavity, and after that, the first resin 20a is provided. Therefore, the second resin 22 is provided in an upper portion of the cavity 50, and the first resin 20 is provided in a lower portion of the cavity 50. When the height of the upper surface of the plunger chip 32 coincides with the height of the bottom surface of the recess part 30A of the lower mold 30, the plunger chip 32 is stopped to be raised. By injecting the resins as above, the first resin 20 comes into contact with the lower surface of the lead frame 12. This step is referred to as an injecting step.

Next, the process is put forward to step S5. In step S5, pressure maintaining and curing are performed. Specifically, a pressure is exerted on the first resin 20 and the second resin 22 from the plunger chip 32, and the pressure is maintained. This step is referred to as a pressure maintaining step. Next, the process is put forward to step S6. In step S6, the plunger chip 32 is moved downward. A molded article is released from the molds, and thereby, the semiconductor device 10 illustrated in FIG. 1 is completed.

In Embodiment 1 of the present invention, the package having the first resin 20 and the second resin 22 is molded by a compression method as mentioned above. This causes less flowing of the resin than a transfer molding method in which resin is provided into a cavity via a narrow runner. Accordingly, the first resin 20 and the second resin 22 are not significantly mixed, which can maintain a state where the first resin 20 and the second resin 22 are substantially separate. By using such a feature of the compression method, the first resin 20 high in heat conductivity can be fed only on the bottom of the lead frame 12. Heat generated by the semiconductor chip 14 is released outside mainly via the lead frame 12 and the first resin 20 high in heat conductivity. Further, the second resin 22 lower in heat conductivity than the first resin 20 can be employed for a portion which is not very important to enhance a heat dissipation property, which thereby can reduce costs for semiconductor devices.

The first resin 20 has a high electric insulation property. Therefore, when the first resin 20 is provided on the lower surface of the lead frame 12, a resin on the bottom of the lead frame 12 can be made thinner than in the case where the second resin the material of which is silica is provided on the lower surface of the lead frame 12. Insulation performance of 450 μm of second resin formed on the bottom of the lead frame 12 is equivalent to insulation performance of 150 μm of first resin 20 formed on the bottom of the lead frame 12. Accordingly, a semiconductor device can be downsized and a heat dissipation property can be improved without impairing insulation performance of the semiconductor device.

In the injecting step and the pressure maintaining step in the method for manufacturing a semiconductor device according to Embodiment 1 of the present invention, the movable pins 42 are brought into contact with the upper surface of the lead frame 12 to prevent the lead frame 12 from floating. Thereby, a defective article can be suppressed from occurring due to floating of the lead frame 12.

With the Embodiment 1 of the present invention, compression molding of resin can be performed using the plunger chip 32 the same as a plunger chip used in the transfer molding method. Therefore, a common plunger mechanism can be shared by different article types.

FIG. 7 is a cross-sectional view of ball plungers 54 and the like which support the plunger rod 34. A supporting table 52 is fixed to the upper surface of a plunger block 51. This supporting table 52 has a recess part, and the lower end part of the plunger rod 34 is housed in the recess part. The lower end part of the plunger rod 34 may be in contact with the supporting table 52, but it is not fixed to the supporting table 52. Ball plungers 54 which can expand and contract in the lateral direction are attached to the supporting table 52. A ball or a pin is provided at a tip part 54A of the ball plunger 54. A body part 54B thereof is connected to this tip part 54A. A spring is included in the body part 54B. Therefore, when load is exerted on the tip part 54A, the body part 54B contracts, and when the load is relieved, the body part 54B resumes its original length. A narrow width part 34a is preferably provided in the plunger rod 34 such that the tip parts 54A of the ball plungers 54 are brought into contact with the narrow width part 34a.

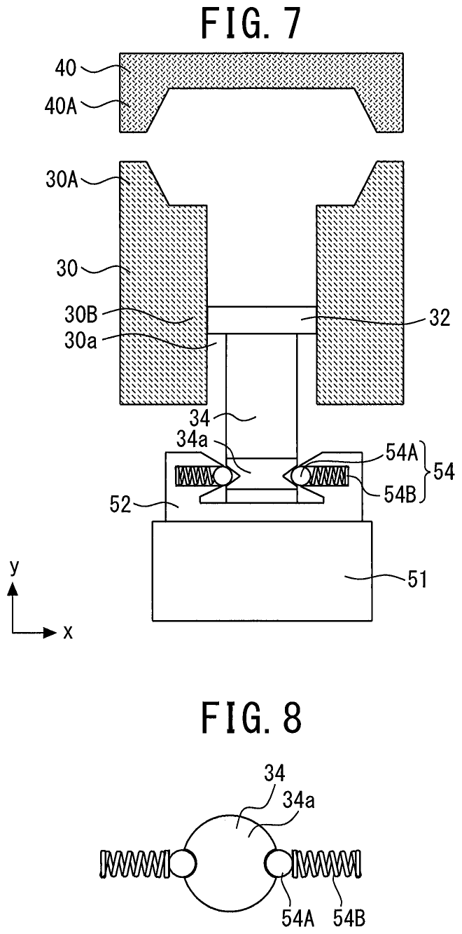

FIG. 8 is a plan view of the plunger rod 34 and the ball plungers 54. Four ball plungers 54 are in contact with the lateral surface of the plunger rod 34. When force is exerted on the ball plungers 54 from the plunger rod 34, the ball plungers 54 contract, which can displace the position of the plunger rod 34 by that amount. Therefore, the plunger rod 34 can be moved in the upward, downward, rightward and leftward directions in plan view and rotated in plan view.

By the plunger block 51 in FIG. 7 moving in the positive and negative y-directions, the plunger chip 32 moves in the hole 30a in the positive and negative y-directions. In this stage, the plunger chip 32 preferably smoothly moves in the pot 30B without the plunger chip 32 exerting strong force on the pot 30B. Therefore, as described with reference to FIGS. 7 and 8, by supporting the plunger rod 34 with the ball plungers 54, the plunger rod 34 is configured to be able to slightly move and rotate. As a result, the plunger chip 32 smoothly moves in the pot 30B without the plunger chip 32 exerting strong force on the pot 30B. The aforementioned method for manufacturing a semiconductor device is preferably implemented using the plunger block 51, the supporting table 52 and the ball plungers 54 illustrated in FIG. 7.

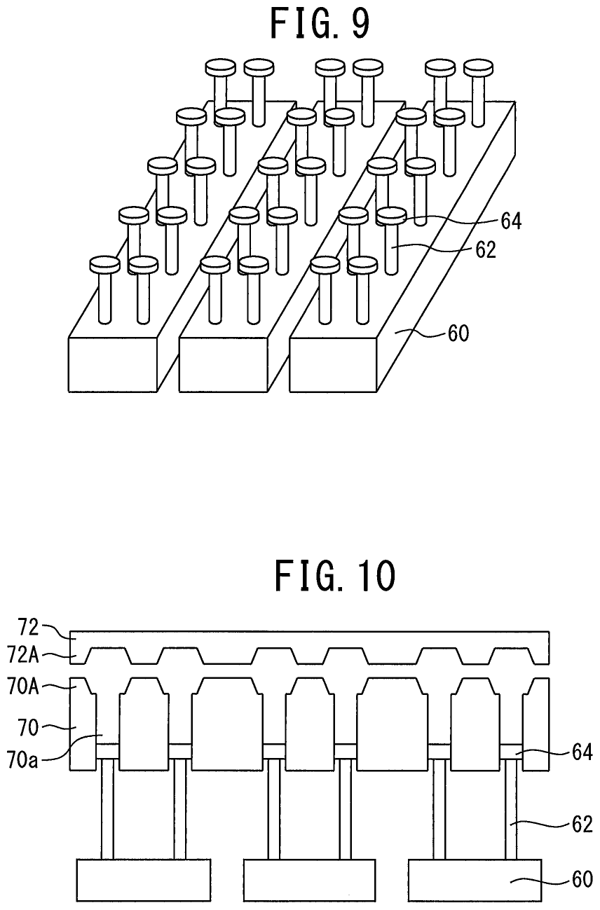

For the method for manufacturing a semiconductor device according to Embodiment 1 of the present invention, injection of resin into one cavity 50 has been described. Nevertheless, a plurality of plunger rods may be fixed to one plunger block to inject resin collectively into a plurality of cavities. FIG. 9 illustrates a plurality of plunger rods 62 provided on one plunger block 60. One plunger chip 64 is fixed to one plunger rod 62. The plunger rods 62 are preferably held in the state where they can be displaced using the aforementioned ball plungers 54.

FIG. 10 is a cross-sectional view of molds and the like corresponding to the plunger apparatus in FIG. 9. A plurality of recess parts 70A are formed in a lower mold 70. One hole 70a is formed in one recess part 70A. A plurality of recess parts 72A are formed in an upper mold 72. Mold clamping of those forms one cavity from one recess part 70A and one recess part 72A, which provides a plurality of cavities. Employing the apparatus illustrated in FIGS. 9 and 10 enables the injecting step and the pressure maintaining step to be performed collectively on the plurality of cavities. Moreover, since resin can be provided to the individual cavities from the plunger chips 64, cull-runner parts are not needed to be provided in the molds. Therefore, the lower mold 70 and the upper mold 72 can be downsized. Moreover, by setting the area of the plunger chip 64 in plan view to be smaller than the area of the bottom surface of the recess part 70A, larger hydrostatic pressure can be exerted on the resin than in the case where these areas are equivalent to each other.

An important feature of the semiconductor device and the method for manufacturing a semiconductor device according to Embodiment 1 is to form a package with two resins which are different in heat conductivity and are not significantly mixed. The semiconductor device and the method for manufacturing a semiconductor device according to Embodiment 1 can be modified as appropriate within a scope not impairing this feature. For example, the amount of the first resin 20 may be increased, and the first resin 20 may be provided above the lower surface of the die pad part of the lead frame 12. Moreover, an intermediate resin having an intermediate heat conductivity between those of the first resin 20 and the second resin 22 may be provided on the first resin 20, and the second resin 22 may be provided on the intermediate resin. In this case, the intermediate resin can promote heat dissipation in the rightward and leftward directions of the semiconductor device 10. Furthermore, for example, the movable pins 42 may be omitted. When a pressure exerted from resin is small, the lead frame 12 is not necessarily fixed with the movable pins 42. The semiconductor chip 14 is not limited to a switching device. For example, a diode may be employed as the semiconductor chip. A plurality of semiconductor chips may be housed in a package, and, for example, an inverter circuit may be constituted of those.

The feature and the modifications described for Embodiment 1 can also be applied to semiconductor devices and methods for manufacturing a semiconductor device according to the following embodiments. Notably, since the semiconductor devices and the methods for manufacturing a semiconductor device according to the following embodiments have many similarities to matters in Embodiment 1, there will be mainly described differences from the matters of Embodiment 1.

### Embodiment 2

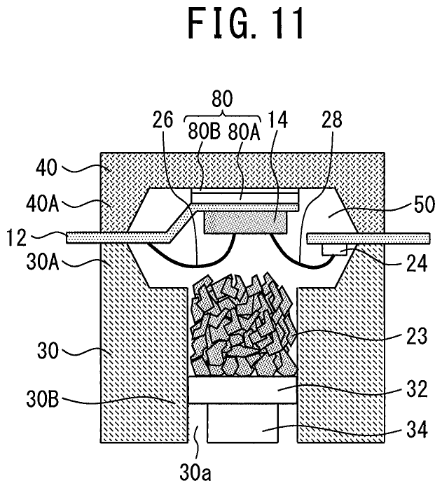

FIG. 11 is a cross-sectional view illustrating a method for manufacturing a semiconductor device according to Embodiment 2. In the method for manufacturing a semiconductor device according to Embodiment 2, first, in the resin providing step, a resin 23 is provided on the plunger chip 32. Next, in the mounting step, the lead frame 12 to the lower surface of which the semiconductor chip 14 is fixed is placed on the upper surface of the recess part 30A. The die pad part of the lead frame 12 is above the semiconductor chip 14.

Next, the process is put forward to the mold clamping step. In the mold clamping step, the upper mold 40 is placed on the lower mold 30 while interposing a heat dissipating sheet 80 between the lead frame 12 and the upper mold 40, and mold clamping is performed in the state where the semiconductor chip 14 is housed in the cavity 50 provided by the lower mold 30 and the upper mold 40. The heat dissipating sheet 80 has, for example, an insulating layer 80A, and a heat sink 80B provided to be stacked on the insulating layer 80A. The insulating layer 80A is preferably molding resin such, for example, as silica and epoxy resin, or the similar material. The material of the heat sink 80B is, for example, copper. The configuration of the heat dissipating sheet 80 is not specially limited as long as the heat conductivity thereof can be higher than that of resin. Upon mold clamping, the upper surface of the heat dissipating sheet 80 comes into contact with the bottom surface of the recess part 40A of the upper mold 40, and the lower surface of the heat dissipating sheet 80 comes into contact with the upper surface of the lead frame 12.

Next, in the injecting step, after the resin 23 is melted, the plunger chip 32 is raised to provide the resin 23 into the cavity 50. In the injecting step, the plunger chip 32 is raised, for example, until the upper surface of the plunger chip 32 becomes equal in height to the bottom surface of the recess part 30A of the lower mold 30. Next, in the pressure maintaining step, a pressure is exerted on the resin 23 from the plunger chip 32, and the pressure is maintained.

Since in Embodiment 1, the first resin 20 high in heat conductivity is brought into contact with the lower surface of the lead frame 12, and the first resin 20 is exposed to the outside, a heat dissipation property of the device can be enhanced. Nevertheless, the first resin 20 will reach its limit when one tries to further enhance the heat dissipation property of the device. Therefore, in Embodiment 2, the heat dissipating sheet 80 is provided to more enhance the heat dissipation property of the device than in the case of using the first resin 20. Since the heat dissipating sheet 80 can enhance the heat dissipation property of the device, high heat conductivity is not required for the resin 23. Therefore, the material of the resin 23 can be one such, for example, as silica which is lower in heat conductivity than alumina.

### Embodiment 3

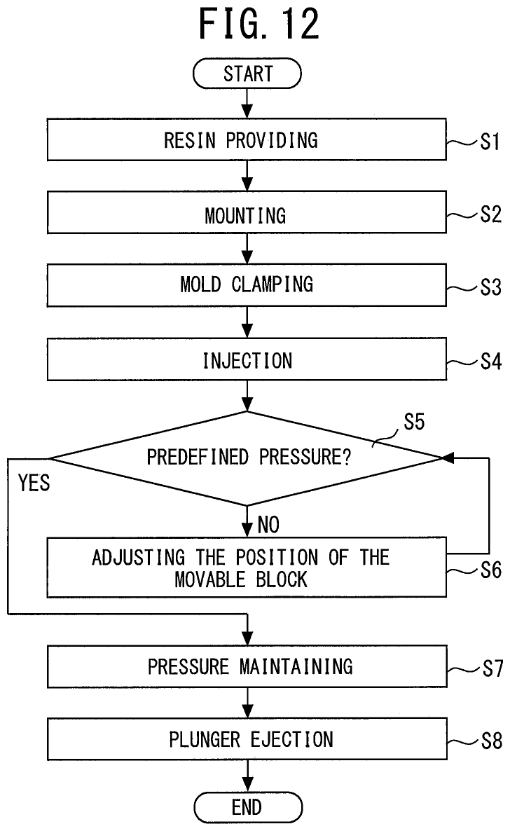

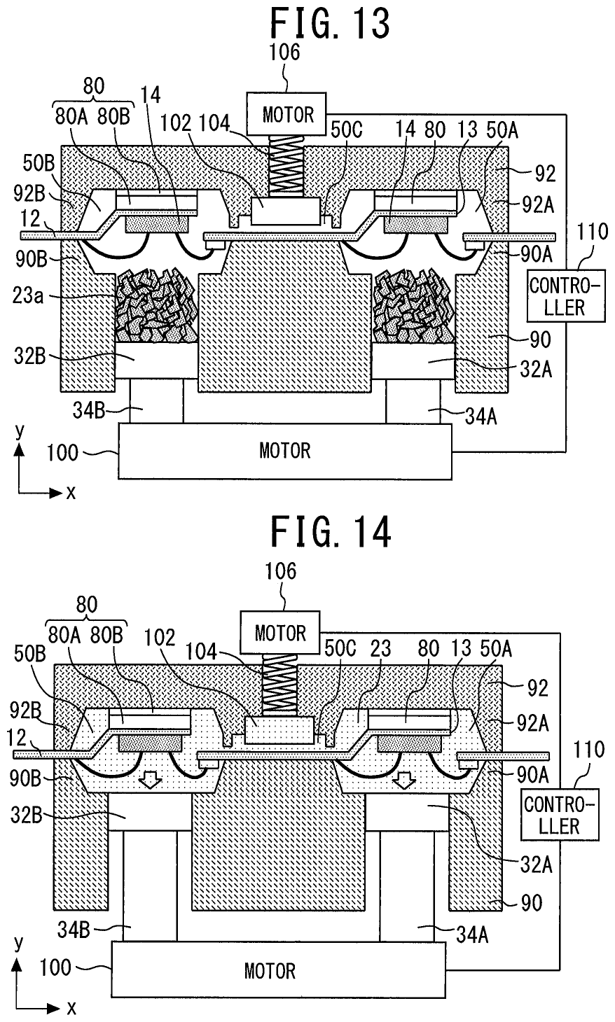

FIG. 12 is a flowchart representing a method for manufacturing a semiconductor device according to Embodiment 3. Before the method for manufacturing a semiconductor device is described with FIG. 12, a configuration of an apparatus used for manufacturing a semiconductor device is described with reference to FIG. 13. At least two recess parts 90A and 90B are formed in a lower mold 90. A plunger chip 32A is in a hole provided in the recess part 90A. The plunger chip 32A is supported on a plunger rod 34A. A plunger chip 32B is in a hole provided in the recess part 90B. The plunger chip 32B is supported on a plunger rod 34B. A motor 100 is connected to the plunger rods 34A and 34B. The motor 100 moves the plunger chips 32A and 32B in the positive and negative y-directions.

The upper mold 92 has at least two recess parts 92A and 92B. A movable block 102 is provided between the recess parts 92A and 92B. The movable block 102 is connected to a motor 106 via a spring 104. The motor 106 can move the movable block 102 in the positive and negative y-directions. Notably, the motors 100 and 106 are preferably servo motors. The motors 100 and 106 are connected to a controller 110.

In the method for manufacturing a semiconductor device according to Embodiment 3, first, the resin providing step is performed in step S1. In the resin providing step, the plunger chips 32A and 32B are provided in the holes formed in the lower mold 90 illustrated in FIG. 13, and the resin 23 is provided on the plunger chips 32A and 32B. Next, the mounting step is performed in step S2. In the mounting step, lead frames 12 and 13 to which semiconductor chips 14 illustrated in FIG. 13 are fixed are placed on the upper surface of the lower mold 90. The lead frame 13 is placed on both the recess parts 90A and 90B.

Next, the mold clamping step is performed in step S3. In the mold clamping step, the upper mold 92 is placed on the lower mold 90. FIG. 13 is a cross-sectional view of the molds and the like after mold clamping. When mold clamping is finished, a cavity 50A is formed by the recess parts 90A and 92A, and a cavity 50B is formed by the recess parts 90B and 92B. The two cavities 50A and 50B are connected to each other with a runner gate 50C. The volume of the runner gate 50C depends on the position of the movable block 102. The volume of the runner gate 50C is small when the movable block 102 is positioned to be low, and the volume of the runner gate 50C is large when the movable block 102 is positioned to be high.

Next, the injecting step is performed in step S4. In the injecting step, after the resin 23 is melted, the plunger chips 32A and 32B are raised to a predefined position on the basis of an instruction of the controller 110. For example, the plunger chips 32A and 32B are raised to the place where the upper surfaces of the plunger chips 32A and 32B coincide with the bottom surfaces of the recess parts 90A and 90B. Thereby, the resin 23 is provided into the cavities 50A and 50B and the runner gate 50C. In this stage, the two plunger chips 32A and 32B are preferably moved by one plunger block. Such a plunger block can be provided in the motor 100.

FIG. 14 is a view illustrating the resin 23 provided into the cavities 50A and 50B and the runner gate 50C. When the plunger chips 32A and 32B are raised to the predefined position, a pressure which the resin 23 in the runner gate 50C exerts on the movable block 102 is detected. This pressure can be detected, for example, by detecting a pressure which the movable block 102 exerts on the motor 106 via the spring 104. For detecting such a pressure, a sensor is provided, for example, inside the motor 106. Information of the detected pressure is reported to the controller 110.

In step S5, it is determined by the controller 110 whether the pressure reported to the controller 110 is a predefined pressure. The “predefined pressure” can take any pressure range. When the detected pressure is larger than the predefined pressure, the controller 110 moves the movable block 102 in the direction of retracting it from the runner gate 50C. Namely, the movable block 102 is moved upward. Thereby, the resin pressure in the cavities 50A and 50B is set to be the predefined pressure.

On the other hand, when the detected pressure is smaller than the predefined pressure, the controller 110 moves the movable block 102 in the direction of advancing it into the runner gate 50C. Namely, the movable block 102 is moved downward. Thereby, the resin pressure in the cavities 50A and 50B is set to be the predefined pressure.

Moving the movable block 102 as above makes the molding pressure and the thickness of the resin uniform. Step S6 is a step of adjusting the position of the movable block 102 as above. Notably, control of the resin thickness can be realized by feeding the positions of the plunger chips 32A and 32B back to the controller 110, and raising the plunger chips 32A and 32B to the predefined position by the controller 110.

When it is determined in step S5 that the detected pressure is the predefined pressure, the process is put forward to step S7. The pressure maintaining step is performed in step S7. In the pressure maintaining step, a pressure is exerted on the resin 23 from the plunger chips 32A and 32B, and the pressure is maintained. Finally, in step S8, the plunger chips 32A and 3213 are moved downward. As above, a product in which one lead frame 13 is provided in a plurality of packages is formed through one molding process.

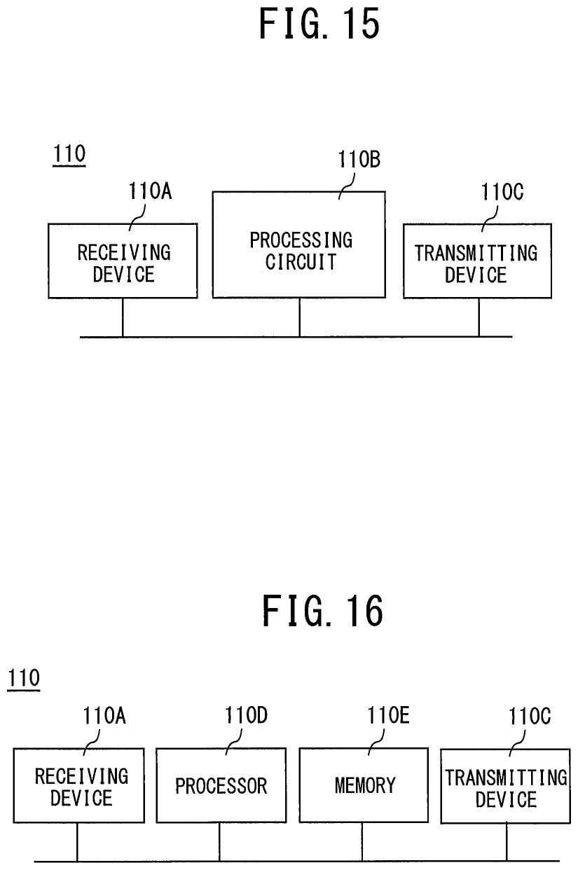

FIG. 15 is a diagram illustrating an exemplary configuration of the controller 110. The controller 110 includes a receiving device 110A, a processing circuit 110B and a transmitting device 110C. The information of the pressure which the movable block 102 exerts on the motor 106 via the spring 104 is transmitted to the receiving device 110A. The aforementioned individual functions performed in the controller 110 are realized by the processing circuit 110B. Namely, in the processing circuit 110B, it is determined whether or not the received pressure is the predefined pressure, and according to the determination result, an amount of moving the movable block 102 is calculated. The processing circuit 110B may be dedicated hardware, or a CPU (also referred to as a Central Processing Unit, a central processing device, a processing device, a calculating device, a microprocessor, a microcomputer, a processor or a DSP) which executes a program stored in a memory. When the processing circuit is dedicated hardware, the processing circuit corresponds, for example, to a single circuit, a composite circuit, a programmed processor, a parallel-programmed processor, an ASIC, an FPGA, or a combination of these. Determination of the pressure, and calculation of the amount of moving the movable block 102 may be realized by separate processing circuits, or those may be collectively realized by one processing circuit.

FIG. 16 illustrates an exemplary configuration of the controller 110 in the case where the processing circuit is a CPU. In this case, the individual functions of the controller 110 are realized by software or a combination of software and firmware. The software or the firmware is described as programs and stored in a memory 110E. The processor 110D realizes the individual functions by reading and executing the programs stored in the memory 110E. Namely, the memory 110E storing the programs with which steps S4 to S8 in FIG. 12 are accordingly to be performed is included. These programs can be also regarded as ones causing a computer to perform the procedures and the methods of steps S4 to S8. The memory herein corresponds, for example, to a nonvolatile or volatile semiconductor memory such as a RAM, a ROM, a flash memory, an EPROM or an EEPROM, a magnetic disk, a flexible disk, an optical disc, a compact disc, a minidisc, a DVD, or the like. Naturally, a part of the aforementioned individual functions may be realized by hardware, and a part thereof may be realized by software or firmware.

According to the semiconductor device and the manufacturing method according to Embodiment 3 of the present invention, the molding pressure and the thickness of the resin can be made uniform by controlling the position of the movable block 102 in accordance with the pressure of the resin 23 fed into the cavities 50A and 50B and the runner gate 50C. Accordingly, a dispersion of insulating properties and heat dissipation properties to the outside between products can be minimized. The method for manufacturing a semiconductor device according to Embodiment 3 can be modified in various manners within a scope not impairing this feature. For example, the number of cavities formed in mold clamping is not limited to two but three or more cavities may be formed.

### Embodiment 4

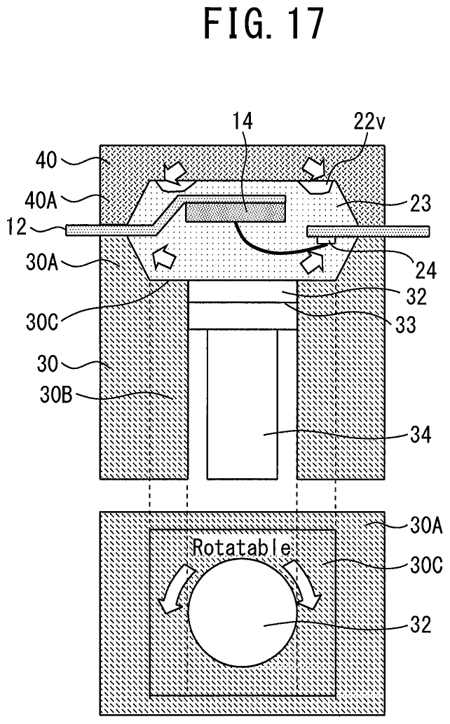

FIG. 17 is a view illustrating a method for manufacturing a semiconductor device according to Embodiment 4. FIG. 17 is a view illustrating the plunger chip 32 and the like in the injecting step. The upper part thereof illustrates a cross-sectional view, and the lower part thereof illustrates a plan view. The plan view in the lower part illustrates that the plunger chip 32 is circular in plan view. Setting the plunger chip 32 to be circular in plan view can more shorten its periphery than a non-circular plunger chip with the same area. In other words, the periphery of the circular plunger chip 32 is smallest out of the peripheries of plunger chips in various shapes. Setting the periphery of the plunger chip 32 to be small can suppress the amount of resin burrs coming between the plunger chip 32 and the pot 30B. Thereby, friction between the plunger chip 32 and the pot 30B can be minimized.

Moreover, a bottom surface 30C of the recess part 30A is quadrangular in plan view. As illustrated in the lower part of FIG. 17, the area of the plunger chip 32 in plan view is smaller than the area of the bottom surface 30C of the recess part 30A. The area of the plunger chip 32 in plan view is preferably not more than a half the area of the bottom surface 30C. Moreover, the plunger chip 32 is preferably at the center of the bottom surface 30C in plan view. Making the area of the plunger chip 32 smaller than the area of the bottom surface 30C can make the resin 23 which is injected into the cavity easily spread from right below the die pad part to the right and the left. The arrows in FIG. 17 indicate flow directions of the resin. Voids 22v are hardly formed right above the semiconductor chip 14. Therefore, a dispersion of heat dissipation properties between products can be suppressed.

A resin ring 33 is provided along the periphery of the plunger chip 32 in order to suppress friction between the plunger chip 32 and the pot 30B due to the plunger chip 32 rising in the hole of the pot 30B. The plunger chip 32 can be protected by the resin ring 33 being mainly in contact with the pot 30B in raising the plunger chip 32.

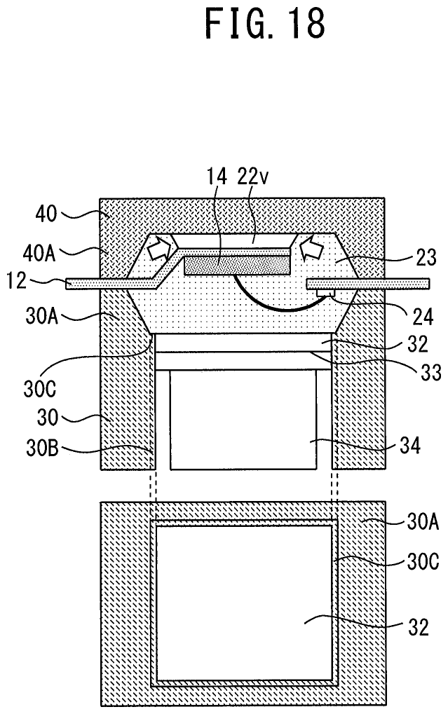

FIG. 18 is a view illustrating a method for manufacturing a semiconductor device according to a comparative example. The upper part thereof illustrates a cross-sectional view, and the lower part thereof illustrates a plan view. The plunger chip 32 of the comparative example is quadrangular in plan view. Moreover, the area of the plunger chip 32 in plan view is equivalent to the area of the bottom surface 30C of the recess part 30A. As above, when the area of the plunger chip 32 is large, the resin tends to stay between the plunger chip 32 and the pot 30B, and the lower mold 30 has to be frequently cleaned.

The arrows in FIG. 18 indicate flows of the resin. Since in the case of the comparative example, the area of the plunger chip 32 is large, an upward flow of the resin 23 is predominant. Therefore, the flow of the resin 23 is disturbed by the die pad part of the lead frame 12. This causes a concern that void 22v arises right above the die pad part and an insulation property of the device cannot be secured.

Meanwhile, in the semiconductor device and the manufacturing method according to Embodiment 4, the area of the plunger chip 32 is made sufficiently smaller than the area of the bottom surface 30C of the recess part 30A of the lower mold 30. Therefore, in the injecting step, rightward and leftward flows of the resin 23 arise in addition of the upward flow of the resin 23. Accordingly, a void right above the die pad part can be suppressed. Providing the plunger chip 32 at the center of the bottom surface 30C of the recess part 30A also contributes to the resin 23 spreading to the corners of the cavity.

Notably, the features of the semiconductor devices and the methods for manufacturing a semiconductor device according to the aforementioned embodiments may be combined.

### DESCRIPTION OF SYMBOLS

10 semiconductor device, 12 lead frame, 14 semiconductor chip, 20 first resin, 22 second resin, 30 lower mold, 30A recess part, 32 plunger chip, 40 upper mold, 40A recess part

1. A semiconductor device comprising:
a lead frame;
a semiconductor chip fixed to an upper surface of the lead frame;
a first resin in contact with a lower surface of the lead frame; and
a second resin provided on the first resin, wherein
the first resin is higher in heat conductivity than the second resin, and
the first resin and the second resin cover the semiconductor chip.

2. The semiconductor device according to claim 1, wherein the first resin is alumina, and the second resin is silica.

3. The semiconductor device according to claim 1, wherein the first resin is exposed below the semiconductor chip, and the second resin is exposed above the semiconductor chip.

4. The semiconductor device according to claim 1, wherein the first resin is provided only below the lower surface of the lead frame.

5. A method for manufacturing a semiconductor device, comprising:
providing a plunger chip in a hole formed in a recess part of a lower mold, providing a first resin on the plunger chip, and providing a second resin lower in heat conductivity than the first resin on the first resin;
placing a lead frame on an upper surface of which a semiconductor chip is fixed on an upper surface of the recess part;
placing an upper mold on the lower mold, and performing mold clamping in a state where the semiconductor chip is housed in a cavity provided by the lower mold and the upper mold;
raising, after melting the first resin and the second resin, the plunger chip to provide the second resin into the cavity, and by providing the first resin after that, bringing the first resin into contact with a lower surface of the lead frame; and
exerting a pressure on the first resin and the second resin from the plunger chip, and maintaining the pressure.

6. The method for manufacturing a semiconductor device according to claim 5, wherein in raising the plunger chip and exerting a pressure on the first resin and the second resin, a movable pin is brought into contact with the upper surface of the lead frame to prevent the lead frame from floating.

7. The method for manufacturing a semiconductor device according to claim 5, wherein the first resin is alumina, and the second resin is silica.

8. A method for manufacturing a semiconductor device, comprising:
providing a plunger chip in a hole formed in a recess part of a lower mold, and providing a resin on the plunger chip;
placing a lead frame on a lower surface of which a semiconductor chip is fixed on an upper surface of the recess part;
placing an upper mold on the lower mold while interposing a heat dissipating sheet higher in heat conductivity than the resin between the lead frame and the upper mold, and performing mold clamping in a state where the semiconductor chip is housed in a cavity provided by the lower mold and the upper mold;
raising, after melting the resin, the plunger chip to provide the resin into the cavity; and
exerting a pressure on the resin from the plunger chip, and maintaining the pressure.

9. The method for manufacturing a semiconductor device according to claim 8, wherein the heat dissipating sheet has an insulating layer, and a heat sink provided to be stacked on the insulating layer.

10. A method for manufacturing a semiconductor device, comprising:
providing plunger chips in holes formed in a lower mold having a plurality of recess parts, and providing resins on the plunger chips;
placing a lead frame to which a semiconductor chip is fixed on an upper surface of the lower mold;
placing an upper mold on the lower mold, and performing mold clamping in a state where a plurality of cavities formed by the plurality of recess parts and a runner gate connecting the plurality of cavities are formed;
raising, after melting the resin, the plunger chips to a predefined position to provide the resin into the plurality of cavities and the runner gate; and
exerting a pressure on the resin from the plunger chips, and maintaining the pressure, wherein
a pressure which the resin in the runner gate exerts on a movable block in the runner gate is detected when the plunger chip is raised to the predefined position, the movable block is moved in a direction of being retracted from the runner gate when the pressure is larger than a predefined pressure, and the movable block is moved in a direction of being advanced into the runner gate when the pressure is smaller than the predefined pressure.

11. The method for manufacturing a semiconductor device according to claim 5, wherein in plan view, an area of the plunger chip is smaller than an area of a bottom surface of the recess part.

12. The method for manufacturing a semiconductor device according to claim 5, wherein in plan view, an area of the plunger chip is not more than a half an area of a bottom surface of the recess part.

13. The method for manufacturing a semiconductor device according to claim 11 or 12, wherein in plan view, the plunger chip is at a center of the bottom surface of the recess part.

14. The method for manufacturing a semiconductor device according to claim 5, wherein the plunger chip is circular in plan view.

15. The method for manufacturing a semiconductor device according to claim 5, wherein
the plunger chip is supported on a plunger rod, and
a ball plunger is brought into contact with a lateral surface of the plunger rod.

16. The method for manufacturing a semiconductor device according to claim 5, wherein raising the plunger chip and exerting a pressure on the first resin and the second resin are performed collectively on a plurality of cavities.
